(19) United States
(12) Patent Application Publication
(10) Pub. No.: US 2020/0159043 A1
(43) Pub. Date: May 21, 2020

(54) SENSING A NOSE POSITION RELATIVE TO AN OPHTHALMIC LENS USING ULTRASOUND

(71) Applicant: Johnson & Johnson Vision Care, Inc., Jacksonville, FL (US)

(72) Inventors: Donald Scott Langford, Melbourne, FL (US); Adam Toner, Jacksonville, FL (US)

(21) Appl. No.: 16/197,239

(22) Filed: Nov. 20, 2018

(51) Int. Cl. G02C 7/04; G02C 7/02; H01L 27/24

(52) U.S. Cl. CPC G02C 7/04; G02C 7/022; H04B 11/00; H01L 27/24; G02C 7/024

(57) ABSTRACT

A first contact lens and a second contact lens each having an electronic system is described herein for spatially locating the position of a wearer's nose relative to each lens. The contact lenses include at least one ultrasound module having at least one transducer such as a pair of transmit and receive transducers, a transceiver transducer or a plurality of transducers. The ultrasound module includes additional components for the creation and reception of the sound pressure wave(s).

### BACKGROUND OF THE INVENTION

### 1. Field of the Invention

The present invention relates to a powered or electronic ophthalmic lens, and more particularly, to a powered or electronic ophthalmic lens having an ultrasound module configured to spatially locate a position of a wearer's nose relative to the lens.

### 2. Discussion of the Related Art

As electronic devices continue to be miniaturized, it is becoming increasingly more likely to create wearable or embeddable microelectronic devices for a variety of uses. Such uses may include monitoring aspects of body chemistry, administering controlled dosages of medications or therapeutic agents via various mechanisms, including automatically, in response to measurements, or in response to external control signals, and augmenting the performance of organs or tissues. Examples of such devices include glucose infusion pumps, pacemakers, defibrillators, ventricular assist devices and neurostimulators. A new, particularly useful field of application is in ophthalmic wearable lenses and contact lenses. For example, a wearable lens may incorporate a lens assembly having an electronically adjustable focus to augment or enhance performance of the eye. In another example, either with or without adjustable focus, a wearable contact lens may incorporate electronic sensors to detect concentrations of particular chemicals in the precorneal (tear) film. The use of embedded electronics in a lens assembly introduces a potential requirement for communication with the electronics, for a method of powering and/or re-energizing the electronics, for interconnecting the electronics, for internal and external sensing and/or monitoring, and for control of the electronics and the overall function of the lens.

The human eye has the ability to discern millions of colors, adjust easily to shifting light conditions, and transmit signals or information to the brain at a rate exceeding that of a high-speed internet connection. Lenses, such as contact lenses and intraocular lenses, currently are utilized to correct vision defects such as myopia (nearsightedness), hyperopia (farsightedness), presbyopia and astigmatism. However, properly designed lenses incorporating additional components may be utilized to enhance vision as well as to correct vision defects.

Conventional contact lenses are polymeric structures with specific shapes to correct various vision problems as briefly set forth above. To achieve enhanced functionality, various circuits and components have to be integrated into these polymeric structures. For example, control circuits, microprocessors, communication devices, power supplies, sensors, actuators, light-emitting diodes, and miniature antennas may be integrated into contact lenses via custom-built optoelectronic components to not only correct vision, but to enhance vision as well as provide additional functionality as is explained herein. Electronic and/or powered ophthalmic lenses may be designed to provide enhanced vision via zoom-in and zoom-out capabilities, or just simply modifying the refractive capabilities of the lenses. Electronic and/or powered contact lenses may be designed to enhance color and resolution.

The proper combination of devices could yield potentially unlimited functionality; however, there are a number of difficulties associated with the incorporation of extra components on a piece of optical-grade polymer. In general, it is difficult to manufacture such components directly on the lens for a number of reasons, as well as mounting and interconnecting planar devices on a non-planar surface. It is also difficult to manufacture to scale. The components to be placed on or in the lens need to be miniaturized and integrated onto just 1.5 square centimeters of a transparent polymer while protecting the components from the liquid environment on the eye. It is also difficult to make a contact lens comfortable and safe for the wearer with the added thickness of additional components.

In addition, because of the complexity of the functionality associated with a powered lens and the high level of interaction between all of the components comprising a powered lens, there is a need to coordinate and control the overall operation of the electronics and optics comprising a powered ophthalmic lens. Accordingly, there is a need for a system to control the operation of all of the other components that is safe, low-cost, and reliable, has a low rate of power consumption and is scalable for incorporation into an ophthalmic lens. Accordingly, there exists a need for a means and method for detecting a nose of the wearer using at least one contact lens.

There are several scenarios where there is a need for powered contact lenses to communicate during normal operation. Methods of detecting and changing lens state for presbyopia, commonly referred to as accommodation, may require the state of the left and right eye to be shared to determine if the lens focus should be changed. In each case, the independent state of each eye must be communicated so that the system controller can determine the required state of the variable lens actuator. There are other cases where it may enhance the user experience if the lens state (e.g., focus state) is changed in a coordinated fashion.

### SUMMARY OF THE INVENTION

Physiological indicators of lens accommodation in the human eye include eye position relative to the nose, and contraction of the ciliary muscle. It follows that detecting physiological indicators such as these can be helpful indicators for triggering certain functionality of a powered ophthalmic lens. For example, data describing the position of the eye relative to the nose can be used to determine whether to trigger accommodation based on models of lens accommodation in a healthy eye under normal conditions.

In at least one embodiment, an ophthalmic lens system includes: a first ophthalmic lens; a second ophthalmic lens; and each ophthalmic lens having at least one ultrasound module including at least two transducers front-facing, where one of the at least two transducers is oriented such that when a sound pressure wave is propagated, the sound pressure wave travels outwardly from the ophthalmic lens, two of the at least two transducers oriented to receive sound pressure waves arriving at the ophthalmic lens, and wherein one of the at least two transducers on the first ophthalmic lens is tuned to a first frequency and another of the at least two transducers is tuned to a second frequency, and one of the at least two transducers on the second ophthalmic lens is tuned to the second frequency and another of the at least two transducers is tuned to the first frequency, and on the first ophthalmic lens one of the at least two transducers is tuned to propagate the sound pressure wave at the first frequency and on the second ophthalmic lens one of the at least two transducers is tuned to propagate the sound pressure wave at the second frequency; a system controller configured to provide control signals to the at least one ultrasound module and to determine the position of the eye relative to the nose based on an amplitude, a wavelength and/or a frequency of at least one received sound pressure wave; a data storage in electrical communication with the system controller; and an actuator in electrical communication with the system controller configured to perform a function in response to at least one control signal from the system controller.

In at least one embodiment, an ophthalmic lens system includes: a first lens; a second lens; each lens having a soft lens portion, a communications module configured for lens to lens communication between the first lens and the second lens, at least one ultrasound module including at least one transmit transducer front-facing and orientated such that when a sound pressure wave is propagated, the sound pressure wave travels outwardly from the ophthalmic lens, and at least a first receive transducer, and a second receive transducer front-facing and oriented to receive incoming sound pressure waves, a system controller in electrical communication with the at least one communications module and the at least one ultrasound module, the system controller configured to provide at least one control signal and receive a corresponding data signal, an actuator in electrical communication with the system controller configured to perform a function in response to a control signal from the system controller; a power source in electrical communication with the system controller, the ultrasound module, and the communications module; and wherein the at least one transmit transducer on the first lens is tuned to a first frequency, the at least one transmit transducer on the second lens is tuned to a second frequency, the at least first receive transducer on each lens is tuned to the first frequency, and the at least second receive transducer on each lens is tuned to the second frequency.

In a further embodiment to either of the previous embodiments, the data storage is a non-volatile memory. In a further embodiment to any of the previous embodiments, each lens further having a timing circuit in electrical communication with the system controller. In a further embodiment to any of the previous embodiments, each lens further having a power source in electrical communication with the ultrasound module and the system controller. In a further embodiment to any of the previous embodiments, each lens includes a communications module in electrical communication with the system controller, the communications module configured to establish a communications link between the first ophthalmic lens and the second ophthalmic lens. In a further embodiment to any of the previous embodiments, the system controller is configured to activate the at least one ultrasound module using at least one predetermined sampling frequency. In a further embodiment to any of the previous embodiments, each lens having an electro-active region for active correction.

In a further embodiment to any of the previous embodiments, the at least one ultrasound module includes a plurality of ultrasound modules distributed around a perimeter of the ophthalmic lens; and wherein the system controller is configured to activate the ultrasound module that produces the strongest output in response to a received sound pressure wave within a predetermined time window, and to deactivate the at least one other ultrasound module on the ophthalmic lens. In a further embodiment to any of the previous embodiments of the previous two paragraphs, the at least two transducers includes a transmit transducer and two receive transducers, and each ultrasound module includes a processor in electrical communication with the system controller, a transmit path having an oscillator in electrical communication with the processor, a burst generator in electrical communication with the oscillator and the system controller, a transmit driver in electrical communication with the burst generator configured to receive a burst signal from the burst generator, the transmit driver drives the transmit transducer; and at least two receive paths each having one of the two receive transducers, at least one receive amplifier in electrical communication with the one of the two receive transducers, and an analog signal processor in communication with the at least one receive amplifier and the system controller; and wherein the processor is configured to control whether the transmit path and the at least two receive paths are activated. In a further embodiment to any of the previous embodiments of the previous two paragraphs, the at least two transducers includes a first transducer and a second transducer, and each ultrasound module includes a processor in electrical communication with the system controller; a switch in electrical communication with the processor; a transmit path having an oscillator in electrical communication with the processor, a burst generator in electrical communication with the oscillator and the system controller, a transmit driver in electrical communication with the burst generator configured to receive a burst signal from the burst generator, the transmit driver drives the first transducer when connected through the switch, and a first receive path having a first receive amplifier in electrical communication with the first transducer through the switch and configured to amplify an output of the first transducer, and a first analog signal processor in communication with the first receive amplifier and the processor; a second receive path having the second transducer, a second receive amplifier in electrical communication with the second transducer through the switch and configured to amplify an output of the second transducer, and a second analog signal processor in communication with the second receive amplifier and the processor; and wherein the processor is configured to control whether the transmit path and the first receive path is activated through the switch based on an operation mode of the ultrasound module between transmit and receive. In a further embodiment to any of the previous embodiments of the previous two paragraphs, each ophthalmic lens includes a power source in electrical communication with the system controller and the at least one ultrasound module; the two transducers includes a transmit transducer and two receive transducers; and each ultrasound module includes a transmit path having an oscillator in electrical communication with the system controller, an amplitude modulation modulator in electrical communication with the oscillator and the system controller, a charge pump in electrical communication with the power source, a transmit driver in electrical communication with the amplitude modulation modulator and the charge pump, the transmit driver configured to receive a signal from the amplitude modulation modulator, and the transmit transducer in electrical communication with the transmit driver; and at least two receive paths each having one of the two receive transducers, a receive amplifier in electrical communication with the one of the two receive transducers and configured to amplify an output of the one of the two receive transducers, an envelope detector in electrical communication with the receive amplifier, and an analog signal processor in communication with the envelope detector and the system controller.

In at least one embodiment, a method of ophthalmic lens accommodation using an ophthalmic lens system with a first ophthalmic lens and a second ophthalmic lens each having at least one ultrasound module having at least two transducers, one of the at least two transducers tuned to a first frequency and another of the at least two transducers tuned to a second frequency, a system controller in electrical communication with the ultrasound module, a timing circuit in electrical communication with the system controller configured to produce a continuous timing signal, an actuator in electrical communication with the system controller configured to perform a function in response to a control signal from the system controller, and a data storage in electrical communication with the system, the method including: propagating from the at least one ultrasound module on each of the first ophthalmic lens and the second ophthalmic lens a sound pressure wave having a frequency for that ophthalmic lens; generating a first signal from the at least one ultrasound module at an earliest of a predetermined time period and upon receipt of one sound pressure wave having the first frequency, where the first signal represents basis for generation; generating a second signal from the at least one ultrasound module at an earliest of the predetermined time period and upon receipt of one sound pressure wave having the second frequency, where the second signal represents basis for generation; receiving the first signal and the second signal by the system controller; setting an accommodation level by the system controller based on the first signal and the second signal; comparing the accommodation level to a current accommodation level for the ophthalmic lens, when the accommodation level is equal to the current accommodation level, then no accommodation change, and when the accommodation level is not equal to the current accommodation level, then generating a control signal by the system controller for the actuator; and changing the current accommodation level by the actuator and storing the changed current accommodation level in data storage in response to the control signal.

In a further method embodiment, the first signal and the second signal are binary with zero representing the predetermined time expired and one representing receipt of the sound pressure wave. In a further method embodiment to either of the method embodiments, the ophthalmic lens system on each lens further includes a communications module configured to establish communications protocol with the other ophthalmic lens, the method further comprising each ophthalmic lens communicating its first signal and its second signal to the other ophthalmic lens.

In a further method embodiment to any of the method embodiments, the method further including synchronizing timing circuits on the first ophthalmic lens and the second ophthalmic lens to each other. In a further method embodiment, wherein setting the accommodation level includes retrieving a truth table by the system controller from the data storage on each ophthalmic lens; selecting a state by each system controller from the truth table based on its first and second signals and the other ophthalmic lens' first and second signals to the truth table, and converting the state to the accommodation by each system controller. In a further embodiment to the first embodiment of this paragraph, wherein setting the accommodation level includes setting the accommodation level to one when the combination of first and second signals indicate the wearer of the ophthalmic lenses is viewing an object within a predetermined range otherwise setting the accommodation level to zero; communicating the respective accommodation levels between the ophthalmic lenses; and maintaining the accommodation level when the respective accommodation levels match otherwise setting the accommodation level to the current accommodation level.

In a further embodiment to any of the above embodiments, the first ophthalmic lens and the second ophthalmic lens are contact lenses or intraocular lenses.

### BRIEF DESCRIPTION OF THE DRAWINGS

The foregoing and other features and advantages of the invention will be apparent from the following, more particular description of preferred embodiments of the invention, as illustrated in the accompanying drawings.

FIG. 1 illustrates a contact lens having at least one ultrasound module, data storage, system controller and actuator in accordance with at least one embodiment of the present invention.

FIG. 2 illustrates a contact lens that has a power source, a timing circuit, and a communications module, in addition to the features outlined in the embodiment of FIG. 1, in accordance with at least one embodiment of the present invention.

FIG. 3 illustrates a system controller with a register.

FIG. 4 illustrates a truth table to interpret ultrasound module output in accordance with at least one embodiment of the present invention

FIGS. 5A-5P illustrate examples of one transmit/receive states in accordance with at least one embodiment of the present invention.

FIG. 6 illustrates an ultrasound module with two receive transducers in accordance with at least one embodiment of the present invention.

FIG. 7 illustrates an ultrasound module with a multiplexed transducer and a receive transducer in accordance with at least one embodiment of the present invention.

FIG. 8 illustrates an ultrasound module with a multiplexed transducer and a receive transducer in accordance with at least one embodiment of the present invention.

FIG. 9 illustrates a diagrammatic representation of an electronic insert, including a pair of transducers, for a powered contact lens in accordance with at least one embodiment of the present invention.

FIG. 10 illustrates a diagrammatic representation of an electronic insert, including three transducers, for a powered contact lens in accordance with at least one embodiment of the present invention.

FIG. 11 illustrates a diagrammatic representation of evenly spaced ultrasound modules/transducers in accordance with at least one embodiment of the present invention.

FIG. 12 illustrates a method for spatially locating a relative position of a wearer's nose in accordance with at least one embodiment of the present invention.

### DETAILED DESCRIPTION OF THE EMBODIMENTS

Conventional contact lenses are polymeric structures with specific shapes to correct various vision problems as briefly set forth above. To achieve enhanced functionality, various circuits and components may be integrated into these polymeric structures. For example, control circuits, microprocessors, communication devices, power supplies, sensors, ultrasound modules, communications modules, and miniature antennas may be integrated into contact lenses via custom-built optoelectronic components to not only correct vision, but to enhance vision as well as provide additional functionality as is explained herein. Electronic and/or powered contact lenses may be designed to provide enhanced vision via zoom-in and zoom-out capabilities, or just simply modifying the refractive capabilities of the lenses. Electronic and/or powered contact lenses may be designed to enhance color and resolution. In addition, ultrasound modules built into the lenses may be utilized to detect blink patterns and/or objects along with communicate with other lenses or external devices.

The powered or electronic contact lens in at least one embodiment includes the necessary elements to monitor the wearer with or without elements to correct and/or enhance the vision of the wearer with one or more of the above described vision defects or otherwise perform a useful ophthalmic function. The electronic contact lens may have a variable-focus optic lens, an assembled front optic embedded into a contact lens or just simply embedding electronics without a lens for any suitable functionality. The electronic lens of the present invention may be incorporated into any number of contact lenses as described above. In addition, intraocular lenses may also incorporate the various components and functionality described herein. However, for ease of explanation, the disclosure will focus on an electronic contact lens intended for single-use daily disposability.

The present invention may be employed in a powered ophthalmic lens or powered contact lens having an electronic system, which actuates a variable-focus optic or any other device or devices configured to implement any number of numerous functions that may be performed. The electronic system includes one or more batteries or other power sources, power management circuitry, one or more sensors, clock generation circuitry, control algorithms and circuitry, and lens driver circuitry. The complexity of these components may vary depending on the required or desired functionality of the lens.

Control of an electronic or a powered ophthalmic lens may be accomplished through a manually operated external device that communicates with the lens through ultrasonic or radio frequency (RF) communication, such as a hand-held remote unit, a phone, a storage container, spectacles, glasses, or a cleaning box. For example, an external device may wirelessly communicate using ultrasound with the powered lens based upon manual input from the wearer. Alternatively, control of the powered ophthalmic lens may be accomplished via feedback or control signals directly from the wearer. For example, ultrasound modules built into the lens may detect blinks, blink patterns, eyelid closures, and/or eye movement depending upon the configuration of the ultrasound modules, which in at least one embodiment include a transmit ultrasound transducer and at least one receive ultrasound transducer, a combination transmit/receive ultrasound transducer, or a combination passive transmit/receive backscatter ultrasound transducer. Based upon the pattern or sequence of blinks and/or movement, the powered ophthalmic lens may change operation state such as change focus of the contact lens. A further alternative is that the wearer has no control over operation of the powered ophthalmic lens.

Because of the complexity of the functionality associated with a powered lens and the high level of interaction between all of the components comprising a powered lens, there is a need to coordinate and control the overall operation of the electronics and optics comprising a powered ophthalmic lens. Accordingly, there is a need for a system to control the operation of all of the other components and in some embodiments provide detection of the nose and communication between the contact lenses that is low-cost and reliable, has a low rate of power consumption, and is scalable for incorporation into an ophthalmic lens.

In at least one embodiment, a sound pressure wave produced at the transmit ultrasound transducer propagates from the contact lens into the field of view. In at least one embodiment, the sound pressure wave includes a burst or multiple sound pressure waves. Objects in the field of view will reflect and/or scatter the sound pressure wave. There is a finite amount of time that passes between the generation of the transmitted sound pressure wave and the return of the reflected signal. This time is determined by the speed of sound in air (typically 343 meters/second) and two times the distance to the object. Two times the distance to the object is used to account for the initial time it takes the sound pressure wave to travel from the transmit ultrasound transducer to the object and the time it takes the reflected wave to travel back to the receive ultrasound transducer. In at least one embodiment, the sound pressure wave is also used for communication.

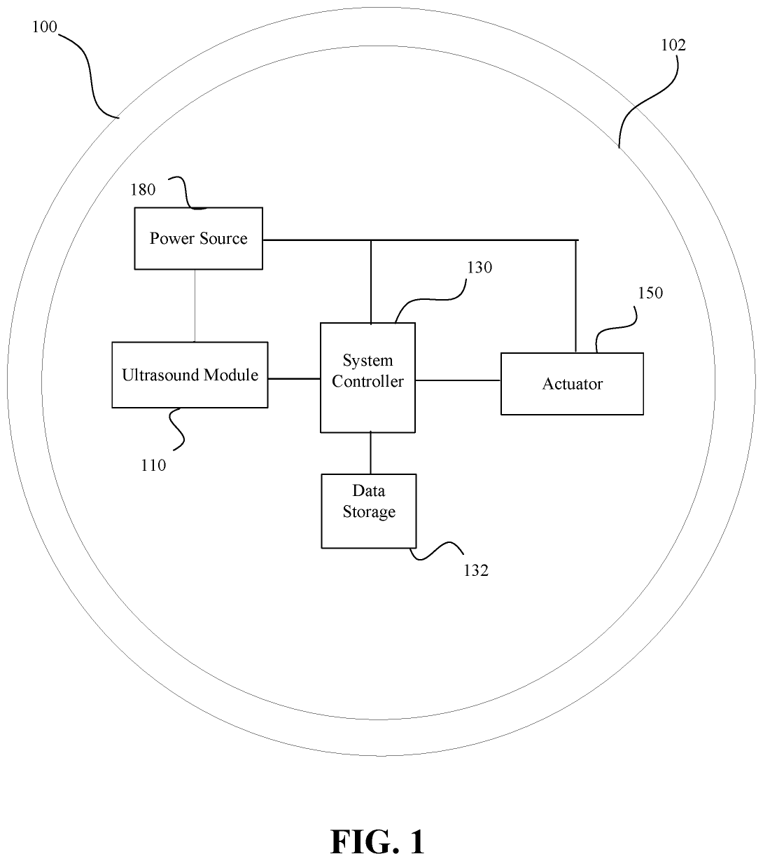

FIGS. 1-3 and 6-8 illustrate different embodiments according to the invention that include a system controller 130 connected to a data storage 132, an actuator 150 and an ultrasound module (collectively referred to as 110) that are on a contact lens 100. The ultrasound module 110 may take a variety of forms including distinct transmit and receive transducers or a shared transmit/receive transducer. Depending on a particular implementation, there may be multiple ultrasound modules 110 present on the contact lens to facilitate particular functionality for the contact lens or multiple transducers connected to one or more ultrasound modules. Many of the figures include an actuator 150 as part of the system with the actuator 150 being representative of, for example, lens accommodation components, data collection components, data monitoring components, and/or functional components such as an alarm.

The system controller 130 in at least one embodiment uses at least one predetermined threshold, template, or a truth table, for interpreting the output of the ultrasound module 110. In another embodiment, the system controller 130 makes use of at least one template (or pattern) to which a series of outputs of the ultrasound module 110 are compared against to determine whether the template has been satisfied, for example based on a match to the pattern and/or a threshold being met, exceeded or less than resulting in the template being satisfied. In at least one embodiment, the problem template includes only at least one threshold. In an alternative embodiment, both thresholds and patterns are used by the system controller 130 to interpret a received series of sound pressure waves. In at least one embodiment as illustrated in FIG. 1, the system controller 130 is in electrical communication with a data storage 132 that stores the threshold(s), template(s) and/or truth table(s). In at least one embodiment, a plurality of templates includes any combination of patterns, thresholds and truth tables. Examples of data storage 132 include memory such as persistent or non-volatile memory, volatile memory, and buffer memory, a register(s), a cache(s), programmable read-only memory (PROM), programmable erasable memory, magneto resistive random access memory (RAM), ferro-electric RAM, flash memory, and polymer thin film ferroelectric memory. In an alternative embodiment, the output(s) of the ultrasound module 110 to the system controller 130 is converted by the system controller 130 into data (or a signal(s)) for control of the actuator 150. In an alternative embodiment, the system controller 130 interprets the output of the ultrasound module 110 using a predefined protocol.

FIG. 1 illustrates a system on a contact lens 100 having an electro-active region 102 with an ultrasound module 110, a system controller 130, a data storage 132, an actuator 150, and a power source 180. In at least one further embodiment, the electro-active region 102 includes an electronics ring around the contact lens 100 on which the electronics are located. The ultrasound module 110 in at least one embodiment has two-way communication with the system controller 130. The actuator 150 receives an output from the system controller 130. In at least one alternative embodiment, the actuator 150 is omitted from one or more of the illustrated embodiments in this disclosure.

The actuator 150 may include any suitable device for implementing a specific function based upon a received command signal from the system controller 130. For example, if a set of data samples matches a template, the system controller 130 may enable the actuator 150 to change focus of the contact lens, provide an alert to the wearer such as a light (or light array) to pulse a light or cause a physical wave to pulsate into the wearer's retina (or alternatively across the lens), or to log data regarding the state of the wearer. Further examples of the actuator 150 acting as an alert mechanism include an electrical device; a mechanical device including, for example, piezoelectric devices, transducers, vibrational devices, chemical release devices with examples including the release of chemicals to cause an itching, irritation or burning sensation, and acoustic devices; a transducer providing optic zone modification of an optic zone of the contact lens such as modifying the focus and/or percentage of light transmission through the lens; a magnetic device; an electromagnetic device; a thermal device; an optical coloration mechanism with or without liquid crystal, prisms, fiber optics, and/or light tubes to, for example, provide an optic modification and/or direct light towards the retina; an electrical device such as an electrical stimulator to provide a mild retinal stimulation or to stimulate at least one of a corneal surface and one or more sensory nerves of the cornea; or any combination thereof. In an alternative embodiment, the actuator 150 sends an alert to an external device using, for example the ultrasound module 110. The actuator 150 receives a signal from the system controller 130 and produces some action based on the signal from the system controller 130. For example, if the output signal from the system controller 130 occurs during one operation state, then the actuator 150 may alert the wearer that a medical condition has arisen or the contact lens is ending/nearing its useful life and/defective. In an alternative embodiment, the actuator 150 delivers a pharmaceutical product to the wearer in response to an instruction from the system controller 130. In an alternative embodiment, the output signal from the system controller 130 during another operation state, then the actuator 150 will record the information in data storage 132 for later retrieval. In a still further alternative embodiment, the signal will cause the actuator 150 to alarm and store information. In an alternative embodiment, the system controller 130 stores the data in the memory (e.g., data storage 132 in other embodiments) associated with the system controller 130 and does not use the actuator 150 for data storage and in at least one embodiment, the actuator 150 is omitted. As set forth above, the powered lens of the present invention may provide various functionality; accordingly, one or more actuators may be variously configured to implement the functionality.

FIG. 1 also illustrates a power source 180, which supplies power for numerous components in the system. The power may be supplied from a battery, energy harvester, or other suitable means as is known to one of ordinary skill in the art. Essentially, any type of power source 180 may be utilized to provide reliable power for all other components of the system. In an alternative embodiment, communication functionality is provided by an energy harvester that acts as the receiver for the time signal, for example in an alternative embodiment, the energy harvester is a photovoltaic cell, a photodiode, or a radio frequency (RF) receiver, which receives both power and a time-base signal (or indication). In a further alternative embodiment, the energy harvester is an inductive charger, in which power is transferred in addition to data such as RFID. In one or more of these alternative embodiments, the time signal could be inherent in the harvested energy, for example N*60 Hz in inductive charging, lighting, or sound including ultrasound.

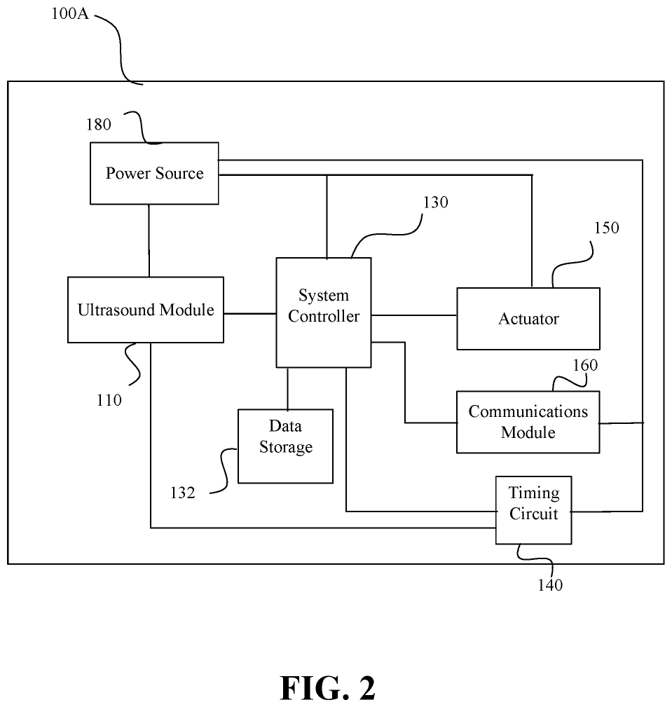

In at least one embodiment as illustrated in FIG. 2, the contact lens 100A including a communications module 160 and a timing circuit 140 being added to the embodiment illustrated in FIG. 1.

Having a communications module 160 in each contact lens being worn by a user permits two-way communication to take place between the contact lenses. The communications module 160 may include any suitable device for effecting wireless communication and is configured to establish communication protocol with another lens and/or an external device. The communications module 160 may include transmitters, receivers, RF transceivers, antennas, interface circuitry for photosensors, and associated or similar electronic components. A communication channel (or link) between the contact lenses may include RF transmissions at the appropriate frequency and power with an appropriate data protocol to permit effective communication between the contact lenses. The communications module 160 may be configured for two-way communication with the system controller 130. The communications module 160 may contain filtering, amplification, detection, and processing circuitry as is common for establishing a communications link. In an embodiment involving RF, the communications module 160 would be tailored for an electronic or powered contact lens, for example the communication may be at the appropriate frequency, amplitude, and format for reliable communication between eyes, low power consumption, and to meet regulatory requirements. The communications module 160 may work in the RF bands, for example 2.4 GHz, or may use light for communication. Information received by the communications module 160 is input to the system controller 130. The system controller 130 may also transmit data from, for example the ultrasound module 110, to the communications module 160, which then transmits data over the communication link to the other contact lens or possibly an external device. In an alternative embodiment, the contact lenses use an ultrasound module to establish the communication link between the contact lenses. In embodiments where the communications module is configured for communicating using encoded ultrasound pressure waves similar to the ultrasound module disclosed herein or alternatively the communications module 160 is the ultrasound module 110. In these embodiments, it is understood that the communications module 160 and ultrasound module(s) 110 may be tuned to different frequencies to avoid interference. In at least one embodiment the communications module transmits information concerning the accommodation state (or level) of the contact lens. In other embodiments the communications module 160 may transmit other information including sensor data, a request for sensor data, a request for confirmation of data interpretation (e.g., direction of focus and/or contact lens orientation), data interpretation, an instruction to perform a function such as with the actuator and/or a predefined function, etc. In certain embodiments, the communications module 160 may have distinct transmit and receive sides that share a multiplexed transducer. A drawback to this configuration is that a short time of flight may not be detected or a received communication may be missed during a transmission or vice versa. As with select alternative embodiments described herein, a delay may be imposed after transmission before the receive amplifier is powered.

The timing circuit 140 provides a clock function for operation of the contact lens. As illustrated the timing circuit 140 is connected to the system controller 130. In at least one embodiment, the timing circuit 140 drives the system controller 130 to send a signal to the ultrasound module 110 to perform a function based on a sampling time interval, which in at least one embodiment is variable based on the output from the ultrasound module 110 to the system controller 130. In an alternative embodiment, the timing circuit 140 may also be added to the embodiment illustrated in FIG. 1. In another alternative embodiment, the timing circuit 140 is part of the system controller 130.

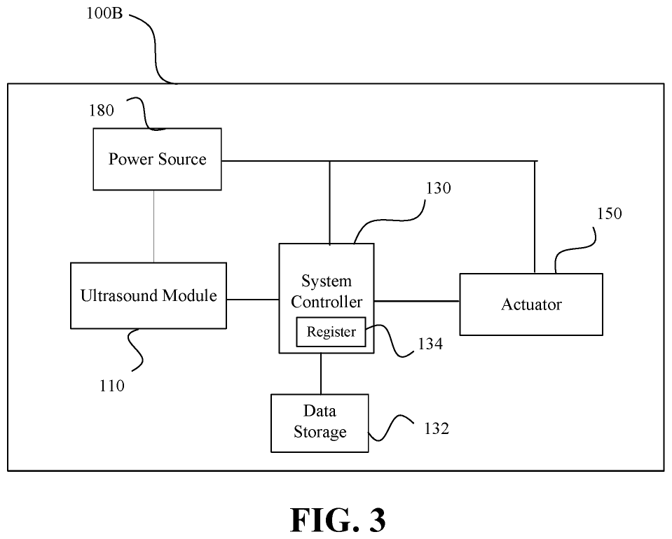

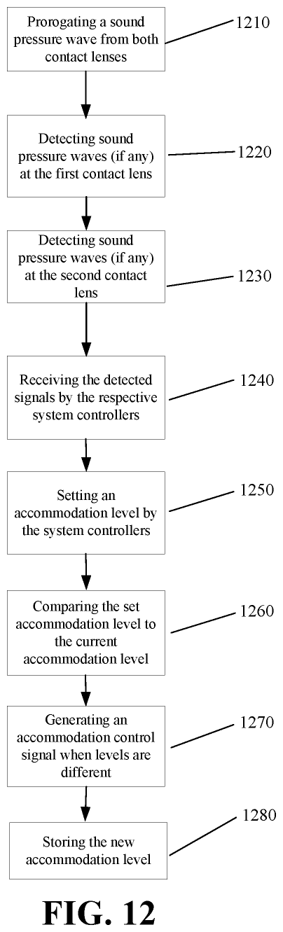

FIG. 3 illustrates the contact lens 100B having the system controller 130 having a register 134 for storing data samples from the ultrasound module 110. In a further embodiment, there is an individual register 134 for each ultrasound module 110 and/or receiving transducer present on the contact lens 100B. The use of a register 134 in at least one embodiment allows for the comparison of data with prior data, a threshold, a preset value, a calibrated value, a target processing value, a template with or without a mask, or a truth table. In a further embodiment, the accommodative state of the lens is stored, in accordance with the method illustrated in FIG. 12 as disclosed herein. In an alternative embodiment, other data storage is used instead of a register(s). In an alternative embodiment, the register 134 is part of the data storage 132.

Based on this disclosure, it should be appreciated that in addition to the presence of the ultrasound module 110 on the contact lens 100 that additional sensors may be included as part of the contact lens to monitor characteristics of the eye and/or the lens. In at least one embodiment, at least a portion of the actuator 150 is consolidated with the system controller 130.

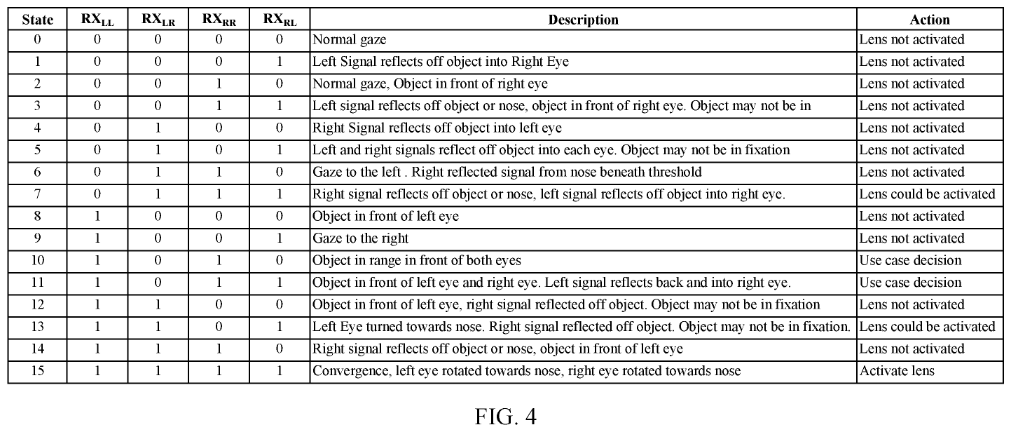

FIG. 4 illustrates an example of a truth table for interpreting the output of the ultrasound module according to at least one embodiment. The template, or truth table, is used by the system controller 130 to determine eye position based on the output of the ultrasound module(s) 110 of each contact lens. When ultrasound module 110 generates an ultrasound pulse at specific gaze angles, sound pressure waves are reflected from the nose into the eye wearing the contact lens that propagated the sound ultrasound pulse and scattered into the other eye. Based on models of the accommodative system in normal functioning eyes, characteristics including amplitude of the detected sound pressure wave (s) can be compared to the truth table illustrated to determine eye position. Thus, the output of the ultrasound module 110 may be used to determine eye position such that the actuator 150 may be configured to provide a desired function, e.g. lens accommodation, when the eyes are in a predetermined position.

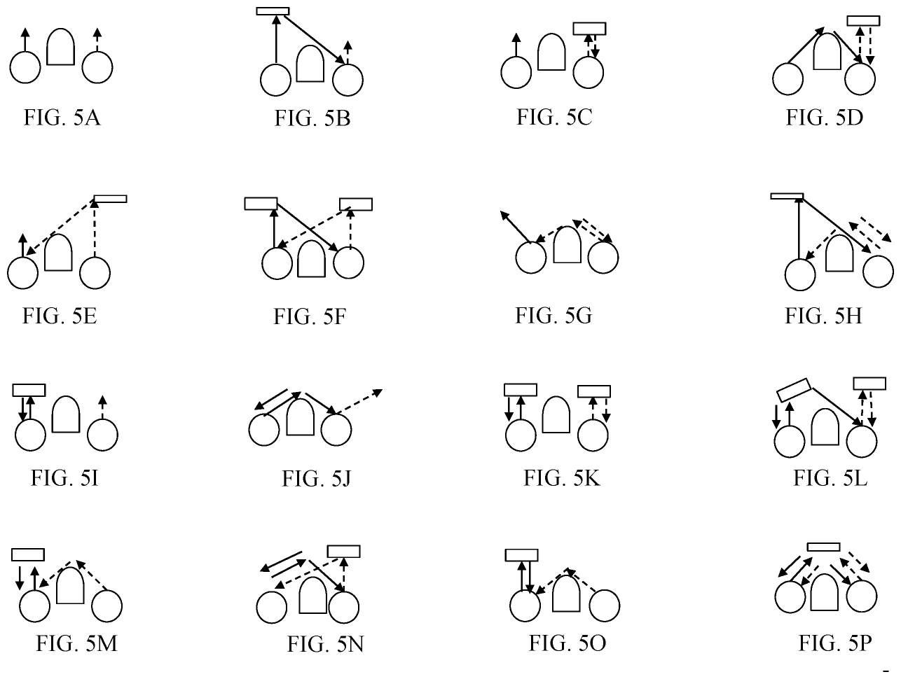

FIGS. 5A-5P illustrates example transmit/receive sensing states that correlate to the truth table illustrated in FIG. 4. Convergence of the wearer's eyes may be determined when at least one sound pressure wave is propagated by the ultrasound module of each of the first and second contact lenses either simultaneously or contemporaneously based on either one of, or a combination of, the amplitude, wavelength, and frequency of the at least one sound pressure wave as it is scattered across the nose or reflected from other objects in the wearer's field of vision. The amplitude, wavelength, and frequency of the sound pressure wave(s) deflected from the nose or other object in the field of view are used to determine time of flight, and ultimately, eye gaze angle. The first contact lens and the second contact lens may be configured to trigger some function, either jointly or independent of the other, based on the output of the ultrasound modules of each of the first and second contact lenses. In at least one embodiment, each contact lens stores data corresponding to its accommodation state. In still further embodiments, having established communications protocol each contact lens communicates stored data, including accommodation state, to the other lens.

In FIGS. 5A-5P, the solid arrow lines represent a left signal originating from the left eye (i.e. the left circle), while the dashed lines represent a right signal originating from the right eye (i.e. the right circle). In the figures with an object, the object is represented by the box. FIG. 5A illustrates state 0 and normal gaze. FIG. 5B illustrates state 1 and a left signal reflecting off of an object into the right eye. FIG. 5C illustrates state 2 and normal gaze with an object in front of the right eye. FIG. 5D illustrates state 3 and a left signal scattering off the bridge of the nose with an object in front of the right eye. FIG. 5E illustrates state 4 and a right signal reflecting off an object into the left eye. FIG. 5F illustrates state 5 and a left signal reflecting off an object into the right eye with a right signal reflecting off an object into the left eye. FIG. 5G illustrates state 6 and gaze to the left with a right signal partially scattering and reflecting off of the bridge of the nose. FIG. 5H illustrates state 7 and a left signal reflecting off an object with a right signal reflecting off the object and/or the bridge of the nose. FIG. 5I illustrates state 8 and a normal gaze with an object in front of the left eye reflecting a left signal. FIG. 5J illustrates state 9 and gaze to the right with a left signal partially scattering and reflecting off of the bridge of the nose. FIG. 5K illustrates state 10 and an object in range of both eyes that reflects back both a left signal and a right signal to the respective eye. FIG. 5L illustrates state 11 and an object in front of the left eye and the right eye where a left signal reflects off the left object into the right eye in addition to both objects reflecting their respective signals back to the source eye. FIG. 5M illustrates state 12 and an object in front of the left eye reflecting a left signal back to the left eye with a right signal reflecting off the object and/or scattering over the bridge of the nose. FIG. 5N illustrates state 13 and the left eye turned towards the nose with a right signal reflecting off an object in front of the right eye into the left eye. FIG. 5O illustrates state 14 and a right signal reflecting off an object in front of the left eye and/or scattering off the bridge of the nose where the object is in front of the left eye causing a left signal to reflect back to the left eye. FIG. 5P illustrates state 15 and convergence of the left and right eyes rotated towards the nose to view an object in front of the nose causing reflection of both signals into both eyes.

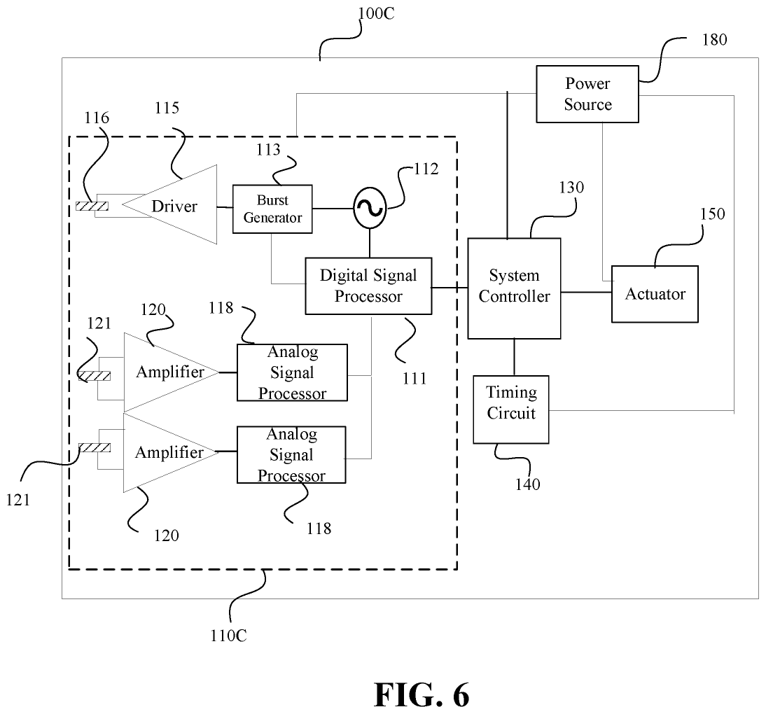

FIGS. 6-8 illustrate different ultrasound modules that illustrate different transmit paths and receive paths examples of paths that facilitate transmitting and receiving sound pressure waves from one or more transducers 116, 121 that start or end with a processor 111 and/or the system controller 130 depending on the example embodiment.

FIG. 6 illustrates a contact lens 100C that includes an ultrasound module 110C having distinct transmit and receive sides (or paths) to the ultrasound module 110C. The illustrated ultrasound module 110C includes a digital signal processor 111, an oscillator 112, a burst generator 113, a transmit driver 115, a transmit ultrasound transducer 116, at least two receive paths, which may be implemented in the other embodiments. FIG. 6 illustrates an example of each receive path having an analog signal processor 118, a receive amplifier 120, and a receive ultrasound transducer 121. One advantage to this configuration, is that the transducers could be configured for different sound frequencies to match the frequency of the transmit path of the same contact lens and the second receive path to match the frequency of the transmit path of the other contact lens. A similar approach may be adopted in the other embodiments where the receive transducer matches the frequency of the transmit transducer of the other contact lens. Each of the receive paths includes the receive ultrasound transducer 121 electrically connected to the receive amplifier 120, which is electrically connected to the analog signal processor 118. The analog signal processors 118 are electrically connected to the digital signal processor 111. In an alternative embodiment, the analog signal processors 118, 118 are consolidated into one analog signal processor 118. In at least one embodiment, the burst generator 113 produces a series of 1's and 0's to facilitate communication with the other lens and/or an external device. In at least one embodiment, the burst generator 113 incorporates a unique identifier for the contact lens based on the amplitude, the frequency, the length, and/or the code modulation of the signal. In a further embodiment, the unique identifier is provided by the system controller 130, the digital signal processor 111, the oscillator 112, and/or the burst generator 113. A similar use of unique identifier may be used with other embodiments in this disclosure. In at least one alternative embodiment for the ultrasound module 110C, the digital signal processor 111 is combined with the system controller 130. In another alternative embodiment, the analog signal processor(s) 118 is combined with the digital signal processor 111 and/or replaced with an analog-to-digital convertor as illustrated in a later figure. The above alternative embodiments may be combined in different combinations to provide further alternative embodiments. In a further embodiment, a third receive path could be added to have a transducer 121 tuned to a frequency of an external device.

The digital signal processor 111 receives a control signal from the system controller 130. In at least one embodiment, the digital signal processor 111 includes a resettable counter and a time-to-digital converter and transmit/receive sequencing controls. The oscillator 112 in at least one embodiment is a switched oscillator. In at least one embodiment, the frequency of the oscillator 112 is programmable through a preset oscillator value, the system controller 130 or external interface (e.g., an interface to an external device). The frequency can be tuned using a reference oscillator and an external interface. In at least one further embodiment, the frequency is set or tuned to a value that minimizes transmit and receive electrical power and allows the transmit ultrasound transducer 116 to produce a sound pressure wave that will have maximum amplitude at the receiver input. In a more particular embodiment, the oscillator 112 is a programmable frequency oscillator such as a current starved ring oscillator where the current and the capacitance control the oscillation frequency where the frequency can be altered by changing the current supplied to the oscillator. In at least one embodiment, the wavelength of the sound pressure wave is tuned based on the dimensions of the transducer used. In a further embodiment, the oscillator 112 varies over time for optimal transmission characteristics. In a still further embodiment, the frequency is calibrated using a reference frequency provided through an external interface and an automatic frequency control (AFC) circuit. The frequency is preset with the AFC tuning it. The frequency can be directly set through the serial interface, which is accessed through the external communications link.

In an embodiment where the time of flight is used, the counter in the digital signal processor 111 begins to count pulses outputted from the oscillator 112. The burst generator 113 gates the oscillator signal for a fixed amount of time defined as the burst length. In at least one embodiment, the burst length is programmable or determined by static timing relationships within the burst generator 113. In such an embodiment, the system controller 130 can use the distance as a cross-check to the nose detection to determine if it is within a range indicative of the eye being in a position to possibly be reading or similar viewing field. In at least one alternative embodiment for the ultrasound module 110C, the digital signal processor 111 is combined with the system controller 130. In another alternative embodiment, the analog signal processor 118 is combined with the digital signal processor 111 and/or replaced with an analog-to-digital convertor as illustrated in a later figure. These two alternative embodiments may be combined to provide a further alternative embodiment.

The output voltage of the burst generator 113 may be level shifted to the appropriate value for the transmit driver 115 and the transmit ultrasound transducer 116. An example of the transmit ultrasound transducer 116 is a piezoelectric device which converts applied burst voltage to a sound pressure wave. In at least one embodiment, the sound pressure wave includes a burst or multiple sound pressure waves. In a further embodiment, the transmit ultrasound transducer 116 is made of any piezoelectric material that is compatible with the power source and the physical properties of the contact lens. Another example of a transducer is a polyvinylidene fluoride or polyvinylidene difluoride (PVDF) film. The sound pressure wave produced by the transmit ultrasound transducer 116 propagates from the contact lens 100 into the field of view. The speed of sound in air typically is 343 meters/second. Accordingly, in an embodiment that measures time of flight, contact lens 100C having ultrasound module 110C for example, then the distance to the object can be measured by dividing the time lapse between the propagation of the sound pressure wave tuned to the frequency of oscillator 112 and receiving the reflected sound pressure wave by the receive ultrasound transducer 121.

The two receive paths in at least one embodiment are turned on with the oscillator 112 or turned on after a predetermined delay after the oscillator 112 is started. When there is a predetermined delay, power for contact lens operation may be lowered during the period of delay. In an embodiment where the receive paths are started with the oscillator 112, the receive amplifiers 120 will receive an output from the receive ultrasound transducer 121 proximate to when the sound pressure wave is output by the transmit ultrasound transducer 116. This output from the receive ultrasound transducer 121 can be used to reset the counter in the digital signal processor 111. In a further embodiment, the detection of the transmit sound pressure wave can be used as an indicator that a true transmit signal has been generated.

A sound pressure wave received by either of the receive ultrasound transducers 121 will produce a voltage signal with a frequency, amplitude, and burst length properties related to the transmitted sound pressure wave. The voltage signal is amplified by the receive amplifier 120 before being sent to the analog signal processor 118, which in an alternative embodiment to embodiments having the receive amplifier 120 and the signal processor 118 are combined into a signal processor. The analog signal processor 118 may include, but is not limited to, frequency selective filtering, envelope detection, integration, level comparison and/or analog-to-digital conversion. Based on this disclosure, it should be appreciated that these functions may be separated into individual blocks with some examples being illustrated in later figures. The analog signal processor 118 produces a received signal that represents the received sound pressure wave at the receive ultrasound transducer 121, which in implementation will have a slight delay. The received signal is passed from the analog signal processor 118 to the digital signal processor 111. When transmission time is used, the digital signal processor 111 will stop the counter that is counting pulses from the oscillator 112 after (or once) the received signal is received. In such an embodiment, the measured time can be compared to a predetermined value to determine whether the nose has been detected. In other embodiments, the digital signal processor 111 interprets the received signal for a message from, for example, the other contact lens or an external device. The resulting output from the digital signal processor 111 is provided to the system controller 130.

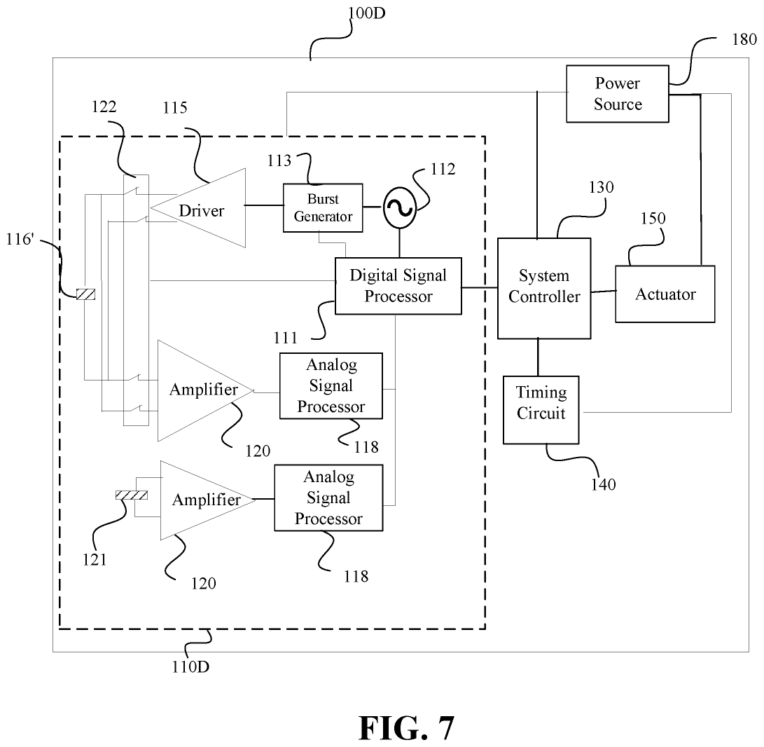

FIG. 7 illustrates a contact lens 100D with an ultrasound module 110D. The illustrated ultrasound module 110D includes a first ultrasound transducer 116′ that is shared by the transmit and receive sides and a second receive ultrasound transducer 121. The first ultrasound transducer 116′ is multiplexed between transmit and receive operation through use of a switch 122. Each of the first transducer 116′ and the second transducer 121 is tuned to the transmission frequency of either the first contact lens or the second contact lens, respectively, such that the ultrasound module can detect sound pressure waves propagated by both the first and the second contact lens. The digital signal processor 111D uses the output of the burst generator 113 to switch the transducer 116′ to transmit mode by connecting the transmit driver 115 to the transducer 116′. When the burst is completed, then the digital signal processor 111D switches the switch 122 to the receive mode by connecting the receive amplifier 120 to the transducer 116′. One advantage to this configuration is that the transducer area is reduced from two transducers to one transducer, but a drawback to this configuration is that a short time of flight may not be detected or if the ultrasound module is being used for communication, then a received communication may be missed during a transmission or vice versa. As with the previous embodiment, a delay may be imposed after transmission before the receive amplifier 120 is powered. The remaining components of the illustrated embodiment remain the same from the prior embodiment.

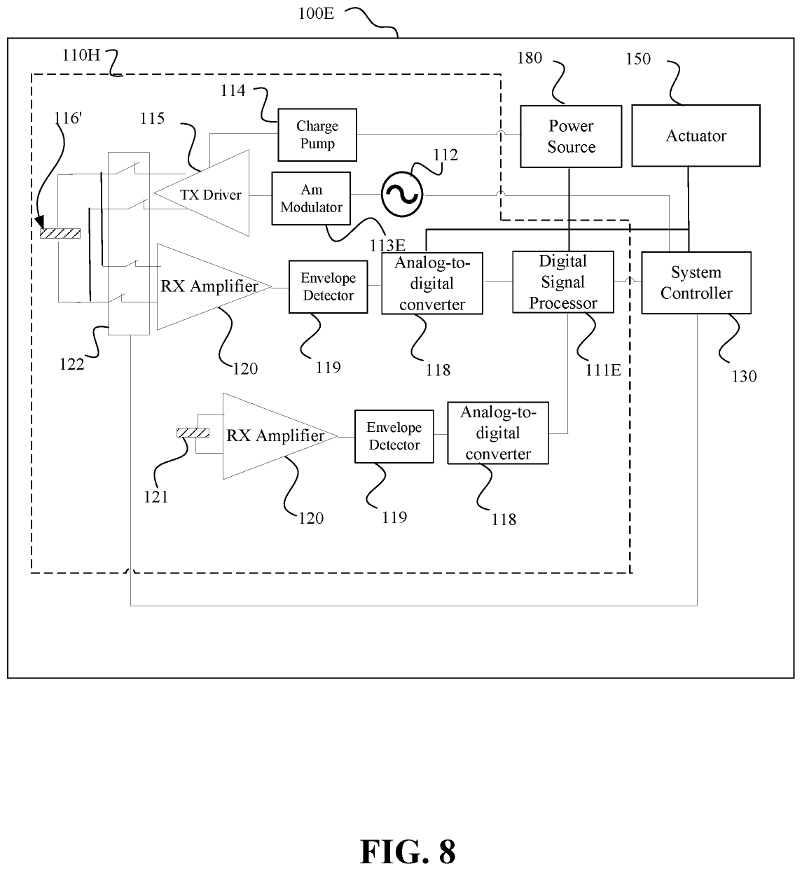

FIG. 8 illustrates a contact lens 100E with an ultrasound module 110E. The illustrated ultrasound module 110E includes a digital signal processor 111E, the oscillator 112, an amplitude modulation (AM) modulator 113E, the charge pump 114, the transmit driver 115 such as a transmit amplifier, the transmit/receive ultrasound transducer 116′ and two receive paths. The first receive path shares the ultrasound transducer 116′ with the transmit path, while the second receive path includes the transducer 121. Each receive path connects its respective transducer 116′, 121 to the receive amplifier 120, the envelope detector 119, and an analog-to-digital converter (ADC) 118E, which each ADC 118E connect to the digital signal processor 111E. The charge pump 114 is electrically connected to the power source 180 and to the transmit driver 115, which provides a voltage to the transmit ultrasound transducer 116′ to create the sound pressure wave to be emitted by the transducer 116′. In at least one embodiment, the transmit driver 115 includes an inverter or an H-bridge, and in further embodiments includes an output driver circuit. In at least one embodiment, the charge pump 114 increases the voltage through the relationship between charge and capacitance with voltage by increasing the charge on a capacitance component(s) (e.g., a capacitor). The voltage output from the charge pump 114, in at least one embodiment, is used as the supply voltage to the transmit driver 115. The transmit driver 115 switches between the output of the charge pump 114 and ground in an alternating fashion in response to the input from the pulse generator 113 to produce an alternating voltage. The alternating voltage is applied by the driver 115 to polarize the material of the transducer 116′ in one direction and then the other direction to create a mechanical stress causing the material to be displaced in a specific direction (i.e. the direction the transducer is facing). The displacement of the transducer material coupled with the shape and the size of the transducer produce the sound pressure wave. Thus, the larger the applied voltage is to the transducer, the larger the stress and thus the larger the displacement and associated sound pressure wave.

The charge pump 114 is also electrically connected to the digital signal processor 111E, which controls operation of the charge pump 114 in at least one embodiment to minimize power consumption by the system by, for example turning off the oscillator 112, the AM modulator 113E, and/or the charge pump 114 at times when the ultrasound module 110E does not need to propagate a sound pressure wave. The envelope detectors 119 turn the high-frequency output of the ultrasound transducers 116′, 121, respectively, into new signals that provide an envelope signal representative of the original output signal to be provided to the respective ADC 118E. This illustrated embodiment has the advantage of simplifying the analysis of the output of the receive ultrasound transducer 121 to determine if a particular threshold has been met for the contact lens 100E to perform a function. The comparators 117 provide a respective output to the digital signal processor 111E, which is in electrical communication with the system controller 130. In a further alternative embodiment, the ADCs 118, 118 are combined into one ADC and/or replaced by an analog signal processor by multiplexing the receive input signals into the ADC 118 and/or the analog signal processor. Further to the previous three alternative embodiments, the digital signal processor 111E is combined with the ADC(s) 118 (or analog signal processor) and/or the envelope detector(s) 119 by multiplexing the receive input signals into the digital signal processor.

In at least one embodiment, the charge pump 114, the AM modulator 113H and transmit driver 115 act as the level shifter and the burst generator. The AM modulator 113E in this embodiment is controlled by the digital signal processor 111E. The circuit works where the oscillator signal is provided to the AM modulator 113E, which in at least one embodiment is an AND gate, and the digital signal processor 111E provides a second clock at a frequency much lower than the oscillator frequency. The output of the circuit is then a sequence of pulses that occur during the positive cycle of the lower frequency. The transmit driver 115 has the appropriate gain to output the modulated signal at the charge pump voltage thus providing level shifting. In an alternative embodiment, the AM modulator 113E is replaced by a pulse generator.

Based on the disclosure connected to FIGS. 6-8, one of ordinary skill in the art should appreciate that the different ultrasound module configurations and transducer/switch configurations may be interchanged and mixed together in different combinations.

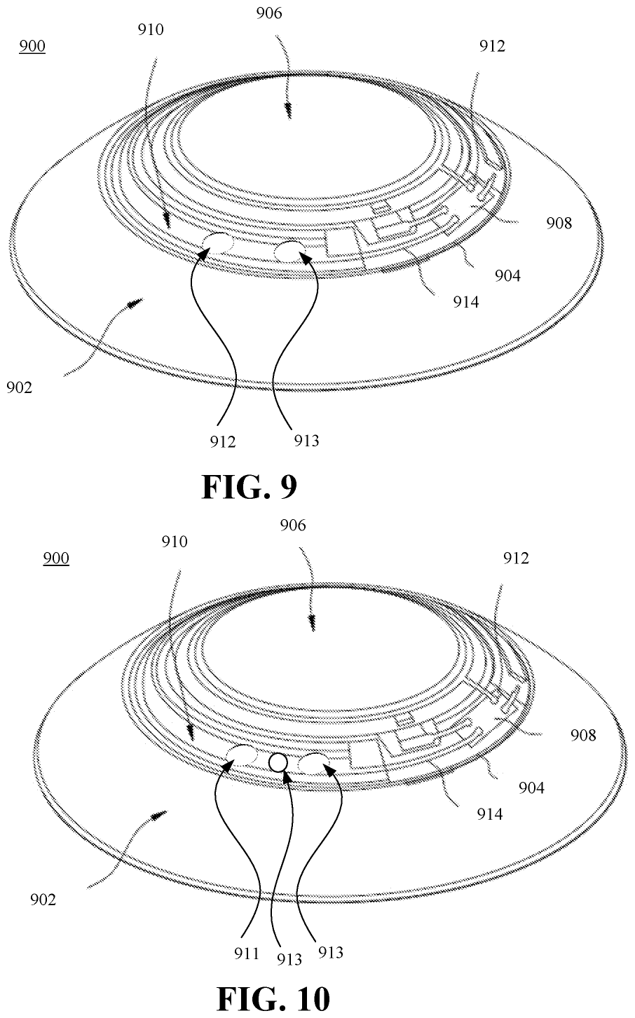

FIG. 9 illustrates a contact lens 900 with an electronic insert 904 having an ultrasound module. The contact lens 900 includes a soft plastic portion 902 which houses the electronic insert 904, which in at least one embodiment is an electronics ring around a lens 906. This electronic insert 904 includes the lens 906 which is activated by the electronics, for example focusing near or far depending on activation (or accommodation level). In at least one embodiment, the electronic insert 904 omits the adjustability of the lens 1006. Integrated circuit 908 mounts onto the electronic insert 904 and connects to batteries (or power source) 910, lens 906, and other components as necessary for the system.

In at least one embodiment, a multiplexed ultrasound transducer 912 and a receive ultrasound transducer 913 are present in the ultrasound module. In at least one embodiment, the integrated circuit 908 includes the multiplexed ultrasound transducer 912 and the receive ultrasound transducer 913 with the associated signal path circuits. The transducers 912, 913 face outward through the lens insert and away from the eye (i.e., front-facing), and is thus able to send and receive sound pressure waves. In at least one embodiment, the transducers 912, 913 are fabricated separately from the other circuit components in the electronic insert 904 including the integrated circuit 908. In this embodiment, the transducers 912, 913 may also be implemented as separate devices mounted on the electronic insert 904 and connected with wiring traces 914. Alternatively, the transducers 912, 913 may be implemented as part of the integrated circuit 908 (not shown). Based on this disclosure one of ordinary skill in the art should appreciate that transducers 912, 913 may be augmented by the other sensors.

FIG. 10 illustrates another contact lens 900′ with an electronic insert 904′ having an ultrasound module. The contact lens 900′ includes a soft plastic portion 902 which houses the electronic insert 904′. This electronic insert 904′ includes a lens 906 which is activated by the electronics, for example focusing near or far depending on activation (or accommodation level). In at least one embodiment, the electronic insert 904′ omits the adjustability of the lens 1006. Integrated circuit 908 mounts onto the electric insert 904′ and connects to batteries (or power source) 910, lens 906, and other components as necessary for the system. The ultrasound module includes a transmit ultrasound transducer 911 and two receive ultrasound transducers 913, 913 with the associated signal path circuits. The transducers 911, 913, 913 face outward through the lens insert and away from the eye, and is thus able to send and receive sound pressure waves. As discussed above, the transducers 911, 913, 913 may be fabricated separately from the other electronic components prior to mounting on the electronic insert 904 or alternatively implemented on the integrated circuit 908 (not shown). The transducers 911, 913, 913 may also be implemented as separate devices mounted on the electronic insert 904′ and connected with wiring traces 914. Based on this disclosure one of ordinary skill in the art should appreciate that transducer 1012′ may be augmented by the other sensors.

In a further embodiment to the embodiments illustrated in FIGS. 9 and 10, the integrated circuit 908, the power source 910 and the transducers 911, 912, 913, 913 are present in an area of the contact lens contained in an overmold, which is a material (such as plastic or other protective material) encapsulating the electronic insert 904. In at least one embodiment, the overmold encapsulates the ultrasound module(s).

In at least one embodiment, the electronics ring of FIGS. 9 and 10 includes an upper surface that is parallel with an imaginary plane on which the contact lens would rest. In at least one embodiment, the ultrasound transducers 912 and 913 are angled relative to the electronics ring and that plane. One example range of the relative angle is 0° to 90°, 0° to 90° including either or both endpoints, 15° to 30°, and 15° to 30° including either or both endpoints. The 0° would be flat to the electronics ring top surface while 90° would be at a right angle to the electronics ring top surface. A benefit to having the transducer angled relative to the electronics ring is to better aim the sound pressure wave emitted towards the nose of the wearer.

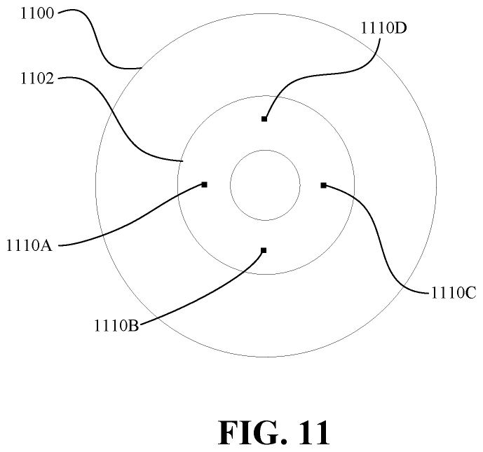

In at least one embodiment as illustrated in FIG. 11 (omits the other components to facilitate presentation clarity), there are a plurality of ultrasound modules 1110A-1110D spaced around the contact lens 1102 on the eye 1100 to increase the fidelity of the communication link between the contact lenses through the nose. Although four ultrasound modules 1110A-1110D are illustrated, it should be appreciated based on this disclosure that a variety of numbers of ultrasound modules may be used with example numbers of ultrasound modules being any number between 2-8, a plurality of ultrasound modules, and at least one ultrasound module. The illustrated ultrasound modules 1110A-1110D are evenly spaced around the periphery of the contact lens 1102 where evenly spaced includes equal distance between the ultrasound modules (i.e., the same distance between neighboring ultrasound modules) and/or balanced about a diameter drawn through the contact lens 1102.

In at least one embodiment, the system controller deactivates the transmission components of the ultrasound module when the respective contact lens is not transmitting. In a further embodiment, the illustrated ultrasound modules are replaced by transducers that are multiplexed together. In a further embodiment for contact lenses that have a plurality of ultrasound modules or at least a plurality of transmit/receive/transceiver transducers, the method includes having the system controller determine which ultrasound module/transducer provides the best response. The system controller selects the ultrasound module/transducer that produces a highest output response to received sound pressure waves. The system controller will deactivate the ultrasound module(s)/transducer(s) that were not selected (i.e., provided a lower signal strength). One benefit to this method is that as the contact lens rotates on the eye, the system controller can change the used ultrasound module/transducer to avoid any ultrasound module/transducer covered by an eyelid and/or for intra-contact communication.

In at least one embodiment where the contact lens includes rotational stability features, then the number of ultrasound modules is one. The angle at which the transducer is relative to the electronics ring may be more severe such that a perpendicular line drawn from the transducer would intersect with the bridge (or just below the bridge) of most wearers of the intended population for the contact lens.

In an embodiment where the ophthalmic lens is an intraocular lens, the intraocular lens will have stability as it is attached to the zonules and ciliary muscle present in the eye. In at least one further embodiment, the intraocular lens will have the transducer(s) installed on the temporal edge (e.g., the far edge from the nose) such that an imaginary perpendicular line drawn from the transducer(s) intersects at or near the bridge of the nose of most wearers of the intended population for the intraocular lens. In such an embodiment, the transducer(s) will be angled relative to the imaginary plane mentioned earlier.

FIG. 12 illustrates a method that may be used with one or more of the above-described system embodiments. The illustrated method provides an example of how a contact lens system having a first lens and a second lens may signal lens accommodation in response to the spatial location of a wearer's nose relative to the lens(es). Ultrasound modules on both the first contact lens and the second contact lens propagate a sound pressure wave at a predetermined frequency, 1210. In at least one embodiment, different transmission frequencies for the first and the second contact lens so that the sound pressure waves can be distinguished. The ultrasound module on the first lens generates a first control signal when the reflected sound pressure wave at a first frequency is detected, 1220, and the second lens generates a second control signal when the reflected sound pressure wave at a second frequency is detected, 1230. The system controller on the first contact lens receives the first control signal and the system controller on the second contact lens receives the second control signal, 1240, with each signal representing a basis for generation of respective sound pressure waves. The system controller on the first contact lens sets an accommodation level based on the first control signal and the system controller on the second contact lens sets an accommodation level based on the second control signal, 1250. In at least one embodiment, when no control signal is received by the system controller, the system controller uses this information to set the accommodation level to distance viewing. The system controller determines whether the accommodation level is equal to the current accommodation level, 1260. The system controller on each lens generates an accommodation control signal to trigger the actuator when accommodation level and the current accommodation level are not equal, 1270. Upon changing accommodation in response to the accommodation control signal the actuator stores the changed current accommodation level in data storage, 1280.

In an alternative embodiment to the method illustrated in FIG. 12, the first control signal and the second control signal are binary where zero represents the predetermined time expired and one represents receipt of the sound pressure wave. Or in a further alternative embodiment, zero represents receipt of the sound pressure wave and one represents the predetermined time expired.

In an alternative embodiment to the method illustrated in FIG. 12, the contact lens system of each lens further includes a communications module configured to establish wireless communications protocol with the other lens, and the method further includes: the first contact lens communicating its first control signal and its accommodation signal to the second contact lens; and the second contact lens communicating its second control signal and its accommodation signal to the first contact lens. In a further alternative embodiment, just one system controller processes the data to select the accommodation level.

In an alternative embodiment to the method illustrated in FIG. 12, the timing circuits on the first contact lens and the second contact lens are synchronized with one another.

In a further embodiment of the previous methods, setting the accommodation level includes the additional steps of: on each lens retrieving a truth table from the data storage; selecting a state from the truth table based on its first and second signals and the other contact lens' first and second signals; and converting the state to the accommodation level. The truth table in this and other embodiments is a template corresponding to gaze angle based on the output of the ultrasound module of each respective contact lens as illustrated in FIGS. 1-3.

In an alternative embodiment of the previous methods setting the accommodation level includes an alternative set of additional steps, including: setting the accommodation level to one when the combination of the first control signal and the second control signal indicate the wearer of the contact lenses is viewing an object within a predetermined range otherwise setting the accommodation level to zero. The first contact lens and the second contact lens transmit a message corresponding to accommodation level to the other contact lens. The actuator on either lens drives a change in the accommodation level when the received accommodation does not match the current accommodation level.

One approach to facilitate the communication between the contact lenses is to implement automatic frequency control for the communication channel. In at least one embodiment, the timing circuit on one contact lens would be the master. The clock synchronization in at least one embodiment will lead the electronics to be biased towards a lens pair to have one be a master. In a further embodiment, the selection of the master contact lens is made post-manufacturing via a software download to the lenses and/or settings change. This approach also could be used to facilitate the dual frequency approach discussed in this disclosure.

In a further alternative embodiment, an external device initiates the configuration sequence for establishing a communication protocol with the contact lens(es) and/or assigns particular functionality to the lens(es). In at least one embodiment, the external device transmits a start signal to the contact lens(es). In at least one embodiment, the contact lens(es) is in low power consumption mode having its transmission components deactivated and only receive components active to conserve power. This operation state may be programmed into the system controller initialization protocol. The received start signal from the external device causes each contact lens(es) to generate a random string. In at least one embodiment, the string is an 8-bit random number. The string may be used to set an 8-bit current steered digital to analog converter, which in turn sets bias current for the oscillator, i.e. the frequency, of each lens. The timing circuit clock function is tuned to the oscillator frequency. Each lens encodes the string and propagates a sound pressure wave corresponding to the string. The external device decodes the received sound pressure wave. Once the external device determines the strings from each lens are different, e.g. each lens is using a different frequency, the external device establishes a communication protocol with each lens. An advantage of this embodiment is encoding two generic lenses for operation as a left lens and a right lens. The external device may be configured with specific software such as an application for a smart phone consistent with this method. It is understood by one of ordinary skill in the art that a suitable external device has capability to propagate sound pressure waves across the frequency band used by the ultrasound module of each contact lens. In further embodiments, this approach may be used to provide a level of customization of each lens for the particular wearer such as distances between the eyes, between one eye or both eyes and the nose, and/or a size information about the wearer's nose.

Although shown and described in what is believed to be the most practical embodiments, it is apparent that departures from specific designs and methods described and shown will suggest themselves to those skilled in the art and may be used without departing from the spirit and scope of the invention. The present invention is not restricted to the particular constructions described and illustrated, but should be constructed to cohere with all modifications that may fall within the scope of the appended claims.

What is claimed is:

1. An ophthalmic lens system comprising:
a first ophthalmic lens;
a second ophthalmic lens; and
each ophthalmic lens having at least one ultrasound module including at least two front-facing transducers, where one of the at least two transducers is oriented such that when a sound pressure wave is propagated, the sound pressure wave travels outwardly from the ophthalmic lens, two of the at least two transducers oriented to receive sound pressure waves arriving at the ophthalmic lens, and wherein one of the at least two transducers on the first ophthalmic lens is tuned to a first frequency and another of the at least two transducers is tuned to a second frequency, and one of the at least two transducers on the second ophthalmic lens is tuned to the second frequency and another of the at least two transducers is tuned to the first frequency, and on the first ophthalmic lens one of the at least two transducers is tuned to propagate the sound pressure wave at the first frequency and on the second ophthalmic lens one of the at least two transducers is tuned to propagate the sound pressure wave at the second frequency;
a system controller configured to:
provide control signals to the at least one ultrasound module and
determine the position of the eye relative to the nose based on an amplitude, a wavelength and/or a frequency of at least one received sound pressure wave;
and
an actuator in electrical communication with the system controller configured to perform a function in response to at least one control signal from the system controller.

2. The ophthalmic lens system according to claim 1 further comprising a data storage in electrical communication with the system controller.

3. The ophthalmic lens system according to claim 1, wherein the data storage stores a truth table.

4. The ophthalmic lens system of claim 1, each lens further having a timing circuit in electrical communication with the system controller.

5. The ophthalmic lens system according to claim 1, each lens further having a power source in electrical communication with the ultrasound module and the system controller.

6. The ophthalmic lens system according to claim 1, wherein each lens includes a communications module in electrical communication with the system controller, the communications module configured to establish a communications link between the first ophthalmic lens and the second ophthalmic lens.

7. The ophthalmic lens system according to claim 1, wherein
the at least one ultrasound module includes a plurality of ultrasound modules distributed around a perimeter of the ophthalmic lens; and
wherein the system controller is configured to activate the ultrasound module that produces the strongest output in response to a received sound pressure wave within a predetermined time window, and to deactivate the at least one other ultrasound module on the ophthalmic lens.

8. The ophthalmic lens system according to claim 1, wherein
the at least two transducers includes a transmit transducer and two receive transducers, and
each ultrasound module includes
a processor in electrical communication with the system controller,
a transmit path having
an oscillator in electrical communication with the processor,
a burst generator in electrical communication with the oscillator and the system controller,
a transmit driver in electrical communication with the burst generator configured to receive a burst signal from the burst generator, the transmit driver drives the transmit transducer; and
at least two receive paths each having
one of the two receive transducers,
at least one receive amplifier in electrical communication with the one of the two receive transducers, and
an analog signal processor in communication with the at least one receive amplifier and the system controller; and
wherein the processor is configured to control whether the transmit path and the at least two receive paths are activated.

9. The ophthalmic lens system according to claim 1, wherein
the at least two transducers includes a first transducer and a second transducer, and
each ultrasound module includes
a processor in electrical communication with the system controller;
a switch in electrical communication with the processor;
a transmit path having
an oscillator in electrical communication with the processor,
a burst generator in electrical communication with the oscillator and the system controller,
a transmit driver in electrical communication with the burst generator configured to receive a burst signal from the burst generator, the transmit driver drives the first transducer when connected through the switch, and
a first receive path having
a first receive amplifier in electrical communication with the first transducer through the switch and configured to amplify an output of the first transducer, and
a first analog signal processor in communication with the first receive amplifier and the processor;
a second receive path having
the second transducer,
a second receive amplifier in electrical communication with the second transducer through the switch and configured to amplify an output of the second transducer, and
a second analog signal processor in communication with the second receive amplifier and the processor; and
wherein the processor is configured to control whether the transmit path and the first receive path is activated through the switch based on an operation mode of the ultrasound module between transmit and receive.

10. The ophthalmic lens system according to claim 1, wherein
each ophthalmic lens includes a power source in electrical communication with the system controller and the at least one ultrasound module;
the two transducers includes a transmit transducer and two receive transducers; and
each ultrasound module includes
a transmit path having
an oscillator in electrical communication with the system controller,
an amplitude modulation modulator in electrical communication with the oscillator and the system controller,
a charge pump in electrical communication with the power source,
a transmit driver in electrical communication with the amplitude modulation modulator and the charge pump, the transmit driver configured to receive a signal from the amplitude modulation modulator, and
the transmit transducer in electrical communication with the transmit driver; and
at least two receive paths each having
one of the two receive transducers,
a receive amplifier in electrical communication with the one of the two receive transducers and configured to amplify an output of the one of the two receive transducers,
an envelope detector in electrical communication with the receive amplifier, and
an analog signal processor in communication with the envelope detector and the system controller.

11. The ophthalmic lens system according to claim 1, wherein the system controller is configured to activate the at least one ultrasound module using at least one predetermined sampling frequency.

12. The ophthalmic lens system according to claim 1, wherein the first ophthalmic lens and the second ophthalmic lens are contact lenses.

13. The ophthalmic lens system according to claim 1, wherein the first ophthalmic lens and the second ophthalmic lens are intraocular lenses.

14. An ophthalmic lens system comprising:
a first lens;
a second lens;
each lens having
a soft lens portion,
a communications module configured for lens to lens communication between the first lens and the second lens,
at least one ultrasound module including at least one transmit transducer front-facing and orientated such that when a sound pressure wave is propagated, the sound pressure wave travels outwardly from the ophthalmic lens, and at least a first receive transducer, and a second receive transducer front-facing and oriented to receive incoming sound pressure waves,
a system controller in electrical communication with the at least one communications module and the at least one ultrasound module, the system controller configured to provide at least one control signal and receive a corresponding data signal,
an actuator in electrical communication with the system controller configured to perform a function in response to a control signal from the system controller;
a power source in electrical communication with the system controller, the ultrasound module, and the communications module; and
wherein the at least one transmit transducer on the first lens is tuned to a first frequency, the at least one transmit transducer on the second lens is tuned to a second frequency, the at least first receive transducer on each lens is tuned to the first frequency, and the at least second receive transducer on each lens is tuned to the second frequency.

15. The ophthalmic lens system according to claim 14, wherein each lens having an electro-active region for active correction.

16. A method of ophthalmic lens accommodation using an ophthalmic lens system with a first ophthalmic lens and a second ophthalmic lens each having at least one ultrasound module having at least two transducers, one of the at least two transducers tuned to a first frequency and another of the at least two transducers tuned to a second frequency, a system controller in electrical communication with the ultrasound module, a timing circuit in electrical communication with the system controller configured to produce a continuous timing signal, an actuator in electrical communication with the system controller configured to perform a function in response to a control signal from the system controller, and a data storage in electrical communication with the system, the method comprising:
propagating from the at least one ultrasound module on each of the first ophthalmic lens and the second ophthalmic lens a sound pressure wave having a frequency for that ophthalmic lens;
generating a first signal from the at least one ultrasound module at an earliest of a predetermined time period and upon receipt of one sound pressure wave having the first frequency, where the first signal represents basis for generation;
generating a second signal from the at least one ultrasound module at an earliest of the predetermined time period and upon receipt of one sound pressure wave having the second frequency, where the second signal represents basis for generation;
receiving the first signal and the second signal by the system controller;
setting an accommodation level by the system controller based on the first signal and the second signal;
comparing the accommodation level to a current accommodation level for the ophthalmic lens,
when the accommodation level is equal to the current accommodation level, then no accommodation change, and
when the accommodation level is not equal to the current accommodation level, then generating a control signal by the system controller for the actuator; and
changing the current accommodation level by the actuator and storing the changed current accommodation level in data storage in response to the control signal.

17. The method according to claim 16, wherein the first signal and the second signal are binary with zero representing the predetermined time expired and one representing receipt of the sound pressure wave.

18. The method according to claim 16, wherein the ophthalmic lens system on each lens further includes a communications module configured to establish communications protocol with the other ophthalmic lens, the method further comprising each ophthalmic lens communicating its first signal and its second signal to the other ophthalmic lens.

19. The method according to claim 16, further comprising synchronizing timing circuits on the first ophthalmic lens and the second ophthalmic lens to each other.

20. The method according to claim 19, wherein setting the accommodation level includes
retrieving a truth table by the system controller from the data storage on each ophthalmic lens;
selecting a state by each system controller from the truth table based on its first and second signals and the other ophthalmic lens' first and second signals to the truth table, and
converting the state to the accommodation by each system controller.

21. The method according to claim 19, wherein setting the accommodation level includes
setting the accommodation level to one when the combination of first and second signals indicate the wearer of the ophthalmic lenses is viewing an object within a predetermined range otherwise setting the accommodation level to zero;
communicating the respective accommodation levels between the ophthalmic lenses; and
maintaining the accommodation level when the respective accommodation levels match otherwise setting the accommodation level to the current accommodation level.
